(19) United States
(12) Patent Application Publication
(10) Pub. No.: US 2010/0188880 A1
(43) Pub. Date: Jul. 29, 2010

(54) POWER SWITCHING FOR PORTABLE APPLICATIONS

(75) Inventor: Barry STAKELY, Snow Camp, NC (US)

Correspondence Address: KENYON & KENYON LLP, 1500 K STREET, NW, WASHINGTON, DC, 20005-1257, US

(73) Assignee: ANALOG DEVICES, INC., Norwood, MA (US)

(21) Appl. No.: 12/473,387

(22) Filed: May 28, 2009

Related U.S. Application Data
(60) Provisional application No. 61/146,683, filed on Jan. 23, 2009.

(51) Int. Cl. G11C 17/00; G11C 5/14; G05F 1/10

(52) U.S. Cl. 365/94; 365/226; 327/536

(57) ABSTRACT

A voltage generation and power switching apparatus, method and system is described. The apparatus includes a digital media processing chip. The digital media processing chip includes a control unit, a one-time programmable memory, a charge pump and a switching network. The control unit is to receive an operating state. The charge pump is connected to a first voltage and configured to generate a second voltage using the first voltage. The control unit activates the charge pump based upon the received operating state. The one-time programmable memory is connected to the charge pump via a switching network. The switching network is configured by the control unit to provide a voltage required by the received operating state to the one-time programmable memory.

### CROSS-REFERENCE TO RELATED APPLICATIONS

This application claims priority to U.S. Provisional Patent Application No. 61/146,683, filed Jan. 23, 2009, entitled “Power Switching For Portable Applications,” which is herein incorporated by reference in its entirety.

### BACKGROUND

Many digital media transmission standards provide for the security of digital media using various methods of encryption. One such method of digital media security is High-bandwidth Digital Content Protection (HDCP). HDCP is used to protect digital media content during transmission between electronic devices. For example, HDCP may protect digital media content during the transfer from a Blu-ray Disc® player to a high-definition television. Further, portable devices may be used to view digital media protected using HDCP. HDCP provides a secure environment for the transmission of digital media content over various digital media connections. The use of HDCP prevents the altering, copying and/or piracy of digital media transferred over High-Definition Multimedia Interface (HDMI) or Digital Visual Interface (DVI) connections, for example. To provide digital media security, HDCP uses a series of encryption keys that are stored in the memory of one or more electronic devices. When new encoded digital media is to be accessed by a digital device, one or more encryption keys needs to be communicated from the memory and used by a decoder to decode the encoded digital media.

Many electronic devices contain HDMI or DVI transmitters and receivers. In many situations, it is desirable to integrate HDCP solutions within a HDMI or DVI transmitter or receiver. An integrated HDCP solution may require the storage of a HDCP key within the memory of an electronic device. There are various solutions for storing a HDCP key within a memory of a electronic device. Current HDCP key storage solutions may use external Electrically Erasable Programmable Read-Only Memory (EEPROM). External EEPROM requires one or more additional pins and power regulating components. These additional pins and power regulating components increase the cost of the chip and increase the probability of chip failure during the manufacturing process. Alternatively, current solutions may use a stacked die architecture in which programmable read-only memory (PROM) is glued to the top of a chip, which also increases the cost of the chip and increase the probability of chip failure during the manufacturing process. As an alternative to EEPROM or a stacked die architecture, on-chip one-time programmable (OTP) memory may be used to store an HDCP key. OTP memory provides several advantages over traditional external EEPROM and stacked die architecture. For example, OTP memory may provide lower cost and better performance. However, OTP memory may require a different voltage than the chip that it is implemented on.

If the OTP memory requires a different voltage than the chip that it is implemented on, the use of two pins is typically required to supply each respective voltage to the chip and the OTP memory. Using an additional dedicated pin for the OTP memory may require an additional regulator and external supply filtering. These additional components increase the cost of the chip. The use of an additional pin may also increase the package size of the chip. For these reasons, the use of an additional pin is not desired. In portable devices, where size and cost is particularly important, it is advantageous to implement solutions that utilize the lowest possible number of pins.

Most portable devices use one or more batteries to provide power to the portable device. Batteries are only capable of storing a finite amount of power that may be used by the portable device. For this reason, power conservation and efficiency is critical. In addition to providing a solution that utilizes the lowest number of pins, it is also desirable to implement the solution in a manner that requires the minimum amount of power.

### BRIEF DESCRIPTION OF THE DRAWINGS

FIG. 1 is a high level block diagram illustrating one embodiment of a voltage generation and power switching apparatus.

FIG. 2 is a logic flow diagram illustrating one embodiment of a OTP read state.

FIG. 3 is a logic flow diagram illustrating one embodiment of a OTP programming state.

FIG. 4 is a logic flow diagram illustrating one embodiment of a OTP quiet state.

FIG. 5 is a logic flow diagram illustrating one embodiment of a method for voltage generation and power switching.

FIG. 6 is a high level block diagram illustrating one embodiment of a voltage generation and power switching system.

### DETAILED DESCRIPTION

Various embodiments include a combination voltage generation and power switching apparatus for portable applications. In one embodiment, the apparatus may include a control unit, an on-chip OTP memory, a switching network and a charge pump. The control unit may receive an operating state. The charge pump may be connected to a first voltage and configured to generate a second voltage using the first voltage. The control unit may activate the charge pump based upon the received operating state. The OTP memory may be connected to the charge pump via a switching network. The switching network may be configured by the control unit to provide a voltage required by the received operating state to the OTP memory.

In one embodiment, the OTP memory may be on-chip memory used to store a HDCP key or other key data that may be used for the encryption of digital data, for example, a HDCP key. The use of on-chip OTP memory provides many advantages. For example, using OTP memory obviates the need for external EEPROM, which typically requires additional external power components and pins. Eliminating the need for additional external power components and pins may allow for a less expensive chip and a smaller chip package. The ability to provide a smaller chip package is particularly important for mobile devices. For example, some mobile devices may require a chip with a small package size. A small package size may only allow for 49 pins on a chip, for example. When dealing with a limited number of pins, saving even a single pin is very beneficial. The use of OTP memory may also eliminates the need for a stacked die architecture in which programmable read-only memory (PROM) is glued to the top of a chip.

When using an on-chip OTP memory, however, the chip that it is implemented on may require a first voltage and the OTP memory may require a second voltage. The first voltage may be less than the second voltage. Typically, separate pins are used to supply voltage to each of the chip and the OTP memory. Instead of using two separate pins to power the chip at the first voltage and the OTP memory at the second voltage, the voltage generation and power switching apparatus may use a single multiplexed pin in conjunction with the charge pump and the switching network. The use of a single multiplexed pin allows for smaller package size and lower cost.

In various embodiments, the voltage generation and power switching apparatus may use a charge pump to generate the voltage required for the OTP memory to perform a read operation. The generated voltage may be provided to the OTP memory over a switching network. The charge pump may be a two stage Dickson charge pump, for example. The voltage provided to the OTP memory by the charge pump may be a different voltage than the supply voltage of the chip that the OTP memory is implemented on. The charge pump may use a chip supply voltage provided over the single multiplexed pin to generate the required voltage for the OTP memory. For example, the OTP memory may require a voltage of 3.3V to perform a read operation and the chip supply voltage may be 1.8V. To supply the voltage of 3.3V to the OTP memory, the charge pump may use the chip supply voltage of 1.8V to generate the second, higher voltage of 3.3V as required by the OTP memory to perform a read operation. In one or more embodiments, the charge pump may utilize an on-chip output capacitor. To utilize an on-chip output capacitor, the system may control the OTP read cycle period and charge pump clock frequency so the voltage sag at the charge pump output is minimized during each bit read.

In one embodiment, the voltage generation and power switching apparatus may use a switching network to provide voltage from the charge pump to the OTP memory. The switching network may include one or more switches. The switching network, which is controlled by a control unit, may provide a chip supply voltage, a voltage from an external pin, a voltage generated by the charge pump or a ground voltage. The control unit may receive a signal identifying an operating state for the OTP memory. Based upon the operating state, a control unit configures the switching network to supply a particular voltage to the OTP memory corresponding to the received operating state.

There are three primary operating states used in conjunction with the OTP memory: OTP Programming State, OTP Read State and OTP Quiet State. OTP Programming State is used during the manufacturing process to burn in a HDCP key into OTP memory. During OTP Programming State, a multiplexed pin or external pin may be used to provide a the required voltage to OTP memory.

During OTP Read State, a memory interface is used to read a HDCP key from the OTP memory. It is during this state that the charge pump may be used to generate the required voltage from a chip supply voltage. The output of the charge pump may be provided over a switching network to a OTP memory to provide the OTP memory with the required voltage during OTP Read State.

The required voltage may be maintained during the entire OTP Read State to protect against the possibility that the required voltage has a higher voltage than the chip supply voltage. If the required voltage were to fall below the chip supply voltage, the OTP memory may consume large amounts of current, which would make the system inappropriate for use in portable, battery-powered product applications. Voltage testers are used to ensure that voltage VDD remains at the proper level. For example, a minimum threshold level and maximum threshold level may be determined. If, for some reason, voltage VDD drops below the minimum threshold level or rises above the maximum threshold level, the OTP Read State may be paused until the voltage supplied by the charge pump reaches an acceptable level. The OTP Read State completes when all encoded key bits have been successfully read from OTP memory and stored within a memory buffer.

After a successful OTP Read State, the HDCP key read from OTP memory is used by a data encoder (decoder) to encode (decode) an un-encoded (encoded) data file. The HDCP key is stored within the encoder (decoder) buffer during the encoding (decoding) process. After the encoded data file has been decoded, the system may enter OTP Quiet State to conserve power and resources.

During the OTP Quiet State, the OTP memory and charge pump may be shut down and grounded until a new authentication needs to be performed. The control unit may instruct the switching network to provide the OTP memory and charge pump with a ground voltage during OTP Quiet State. The system may include an additional memory unit (i.e. 1K RAM) or decoder memory buffer to store a successfully decrypted HDCP key. Once an authentication has been performed for a particular data file, the decrypted key can be retrieved from the additional memory during key re-authentication. This allows the OTP memory and charge pump to remain idle after a successful OTP read state.

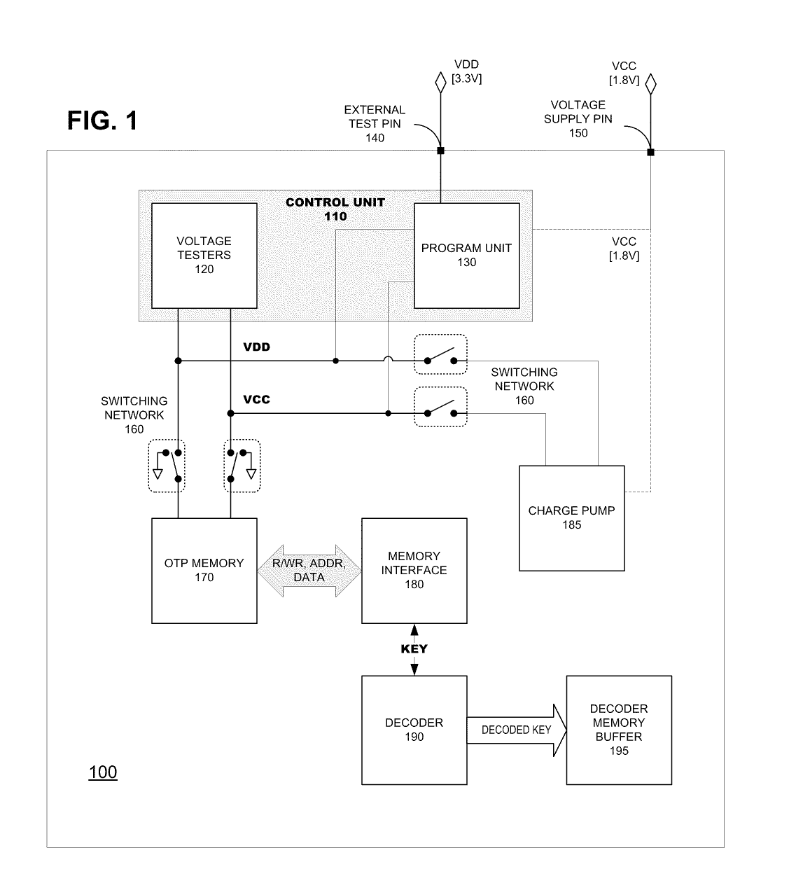

FIG. 1 illustrates one embodiment of a voltage generation and power switching apparatus. The voltage generation and power switching apparatus may include digital media processing chip 100 comprising control unit 110, charge pump 185, OTP memory 170 and switching network 160.

In various embodiments, control unit 110 may include program unit 130. Program unit 130 may be used to program OTP memory 170 during OTP programming state. During OTP programming state, OTP memory 170 may be programmed with one or more digital media protection keys. For example, OTP memory 170 may be programmed with a HDCP key or series of HDCP keys. The digital media protection key programmed within OTP memory 170 may be used to encode or decode digital media data. The embodiments, however, are not limited to this example.

In various embodiments, control unit 110 may include voltage testers 120. Voltage testers 120 may test voltages VDD and VCC to ensure that they meet required voltage levels for a current operating state. In one embodiment, during each operating state, voltage testers 120 may test voltages VDD and VCC to ensure they do not fall below a minimum threshold level or rise above a maximum threshold level. For example, operating state OTP read state may require a voltage of 3.3V for the OTP memory. A minimum threshold voltage for OTP read state may be 2.9V. During an OTP read state, if voltage testers 120 determine that the voltage provided to OTP memory has dropped below the minimum threshold level, voltage testers 120 may pause the OTP read state until a proper voltage level can be maintained. Additionally, voltage testers 120 may test voltages VDD and VCC to ensure that voltage VDD stays greater than voltage VCC. The embodiments, however, are not limited to this example.

Control unit 110 may be responsible for power delivery throughout digital media processing chip 100. For example, control unit 110 may receive an operating state for the OTP memory. Based upon the received operating state, control unit 110 may provide a voltage required by the received operating state using switching network 160. Switching network 160 may contain one or more switches and connections. As illustrated, switching network 160 includes four switches, however, more or less switches may be used. Switching network 160 is configured by control unit 100 to provide a required voltage to the one-time programmable memory based upon the received operating state. For example, during OTP quiet state, control unit 110 may instruct switching network 160 to provide ground voltage to OTP memory.

In various embodiments, digital media processing chip 100 may include charge pump 185. Charge pump 185 may include one or more capacitors. Digital media processing chip may require a first chip supply voltage, VCC, for example. OTP memory 170 may require a second, higher voltage, VDD, for example. However, only a single voltage supply pin may be available due a small package size of digital media processing chip 100. Voltage VCC may be provided to digital media processing chip 100 via voltage supply pin 150. During operating states that require the use of OTP memory 170, digital media processing chip 100 may use charge pump 185 to generate voltage VDD using voltage VCC. Utilizing voltage testers 120, control unit 110 monitors the voltage generated by charge pump 185. Once the required voltage VDD is reached, control unit 110 instructs switching network 160 to provide voltage VDD from charge pump 185 to OTP memory 170.

In various embodiments, digital media processing chip 100 may include memory interface 180. Memory interface 180 may be used to read or write data to one or more memory units. Memory interface 180 may be used during certain operating states to read or write data to OTP memory 170. For example, during OTP read state, memory interface 180 may read data from OTP memory. The data may include a key used to decode digital media data such as a HDCP key.

In various embodiments, digital media processing chip 100 may include decoder 190 and decoder memory buffer 195. Decoder 190 may include a processor, memory, program instructions and/or logic. Decoder memory buffer 195 may include dynamic random access memory, static random access memory, flash memory or other memory known in the art. Memory interface 180 communicates data read from the OTP memory to decoder 190. Decoder 190 is used to decode key data, for example. Decoder 190 may communicate a decoded key to decoder 195. Storing a decoded key in decoder memory buffer 195 prevents future reads of OTP memory to obtain the same key in the future, thus, providing efficiency to digital media processing chip 100.

There are three primary operating states that may be used in conjunction with the OTP memory: OTP Read State, OTP Programming State, and OTP Quiet State.

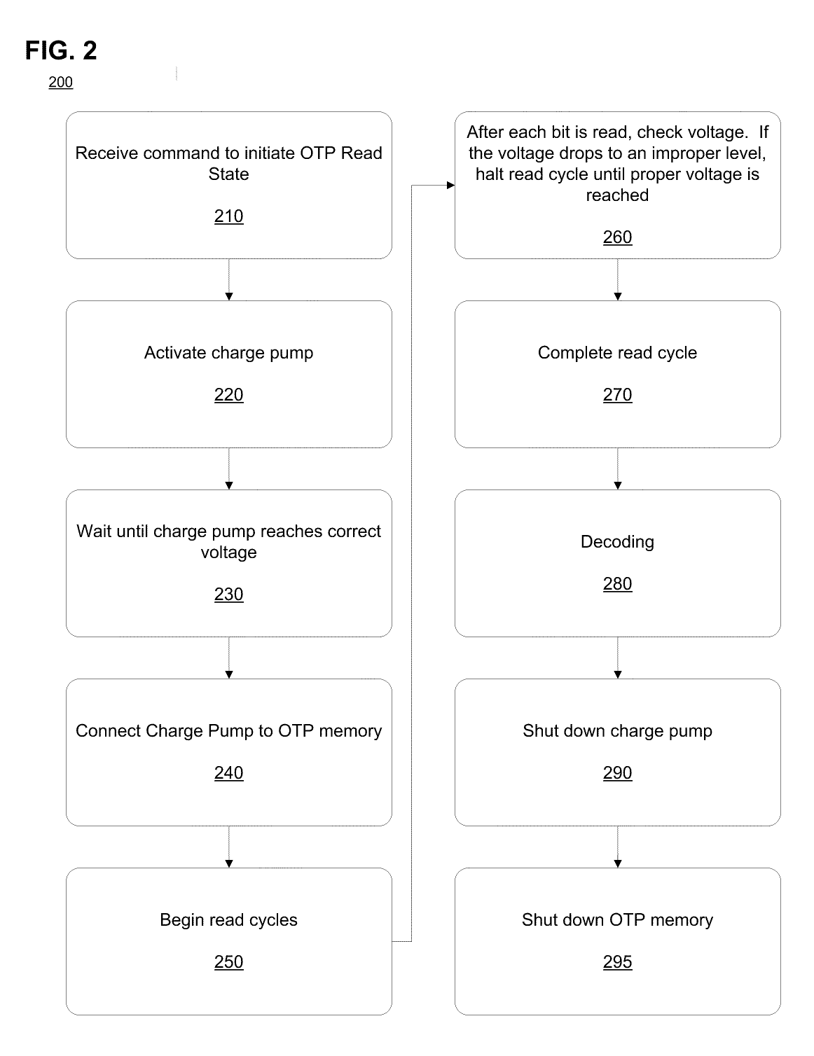

FIG. 2 illustrates one embodiment of an OTP read state. At block 210, a command is received that initiates the OTP read state. The command may be received by a control unit. The command may be sent to the control unit by a controller located within a digital media device. In one embodiment, OTP read state initiates a read of an OTP memory. OTP memory may be implemented on a digital media processing chip. In one embodiment, OTP memory may require a voltage that is different than the digital media processing chip. For example, a digital media processing chip may require a supply voltage of 1.8V. OTP memory may require a voltage of 3.3V for a read operation. In one embodiment, the digital media processing chip may only include a single pin providing the 1.8V chip supply voltage. In this case, a charge pump may be used to generate the 3.3V supply for the OTP memory read operation.

At block 220, the charge pump is activated. The charge pump may be activated using an “on” signal received from a control unit. The charge pump may use the chip supply voltage to generate a new voltage required by the OTP memory to perform a read operation. The new voltage may be greater than the chip supply voltage. The charge pump may include one or more integrated output capacitors or other capacitors that are used to generate and store the new generated voltage.

At block 230, the system waits until the correct voltage has been reached by the charge pump. Voltage testers may be used to monitor the voltage level of the charge pump and send a charge pump ready signal to a control unit once the proper voltage has been reached.

At block 240, the charge pump is connected to OTP memory using a switching network after the charge pump has reached the proper voltage level for an OTP read operation. The control unit instructs the switching network to provide the generated voltage to OTP memory. The appropriate switches are then activated to provide the generated voltage from the charge pump to the OTP memory. For example, a switch may be closed to stop providing the chip supply voltage and another switch opened to provide the new generated voltage from the charge pump to the OTP memory.

At block 250, the read cycle begins on the OTP memory. During the read cycle, data is read from the OTP memory. The data read from OTP memory may include key data, for example, a HDCP key.

At block 260, the voltage is checked after each bit is read to ensure that the proper voltage level is maintained during the read state. Voltage testers may alert the control unit if the voltage has dropped or sags to an improper level. If this occurs, the read cycle will be paused and will resume once a proper voltage level has been reached by the charge pump. During the pause, the switching network may be used to change the voltage supplied to the OTP memory.

At block 270, the read cycle have been completed when all bits have been read from the OTP memory. Once all necessary bits have been read from the OTP memory, a decoder is used to decode the data, which may include key data. Alternatively, as each bit is read during the read cycle, a decoder may decode the bit.

At block 280, the decoder is used to decode the key data read from OTP memory. The decoded key data key may be buffered within the decoder and may be used to decode encoded data. After the key data has been decoded, it may be stored in a decoder memory buffer. Storing the decoded key data within a decoder memory buffer obviates the need to re-read OTP memory to retrieve the same key data. In one or more embodiments, the decoder may also periodically refresh key data.

At block 290, the charge pump is shut down and voltage is grounded to conserve power and resources. At block 295 the OTP memory is shut down and voltage is grounded to conserve power and resources.

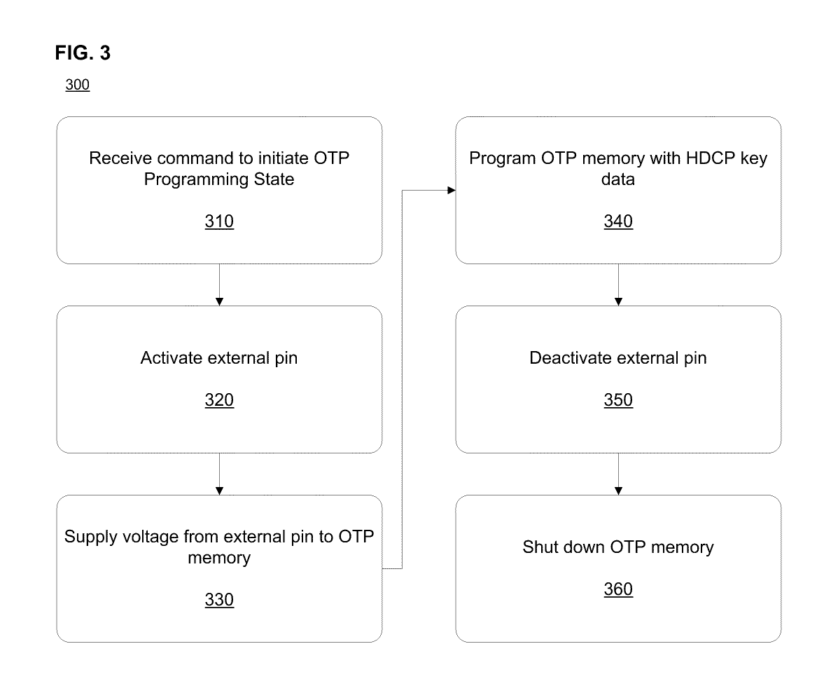

FIG. 3 illustrates one embodiment of an OTP programming state. OTP programming state is used to program data into the OTP memory. The programming of OTP memory may take place during the manufacturing process. Alternatively, programming may take place at any time prior to an initial OTP read state. During OTP programming state, an external multiplexed pin may be used to provide voltage from an external source to the OTP memory.

At block 310, a command is received that initiates the OTP programming state. The command may be received by a control unit. The command may be sent to the control unit by a controller located within a digital media device such as an HDMI or DVI transmitter or receiver.

At block 320, an external pin is activated. The external pin may be a multiplexed pin used to provide voltage VDD during the manufacturing process. After the manufacturing process, the external supply pin may not be needed. For example, OTP programming state may utilize a normal I/O chip pin (i.e. INTERRUPT pin) to supply voltage VDD to the OTP memory during programming. The embodiments, however, are not limited to this example.

At block 330, voltage from the external pin is supplied to the OTP memory. The voltage supplied to the OTP memory may be different than the voltage required by the chip that the OTP memory is implemented on.

At block 340, the OTP memory is programmed. The OTP memory may be programmed with key data, circuit calibration values, chip ID values, and revision data. The OTP memory may be programmed with one or more digital media protection keys. For example, OTP memory may be programmed with a HDCP key or series of HDCP keys. The embodiments, however, are not limited to this example.

At block 350, the external pin may be deactivated after the programming of the OTP memory has completed. At block 360, the OTP memory may be shut down and voltage is grounded using a switching network to conserve power and resources.

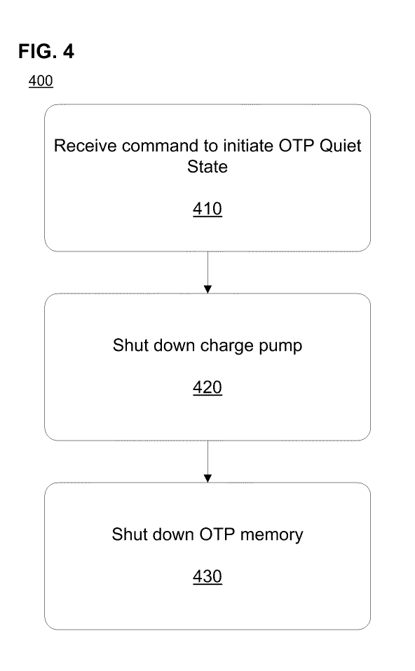

FIG. 4 illustrates one embodiment of an OTP quiet state. In various embodiments, the OTP memory may only be used during short periods of time. For example, an OTP read state may take a short period of time to read one or more digital content protection keys from OTP memory. After the one or more digital content protection keys have been read from OTP memory, they may be stored in another memory for reuse during re-authentication. The system may include an additional memory unit (i.e. 1K RAM) or a decoder memory buffer to store a successfully read digital content protection key. Once an authentication has been performed for a particular data file, the digital content protection key can be retrieved from the additional memory during the playback of the file. To conserve system resources, OTP quiet state may be initiated. This allows the OTP memory and the charge pump to remain idle after a successful OTP read state.

At block 410, a command is received that initiates the OTP quiet state. The command may be received by a control unit. The command may be sent to the control unit by a controller located within a digital media device such as an HDMI or DVI transmitter or receiver.

At block 420, the charge pump is shut down and voltage is grounded to conserve power and resources. The control unit may send an “off” signal to the charge pump to conserve resources during an OTP quiet state. At block 430, the OTP memory is shut down and voltage is grounded to conserve power and resources. A control unit may instruct the switching network to provide a ground voltage to OTP memory.

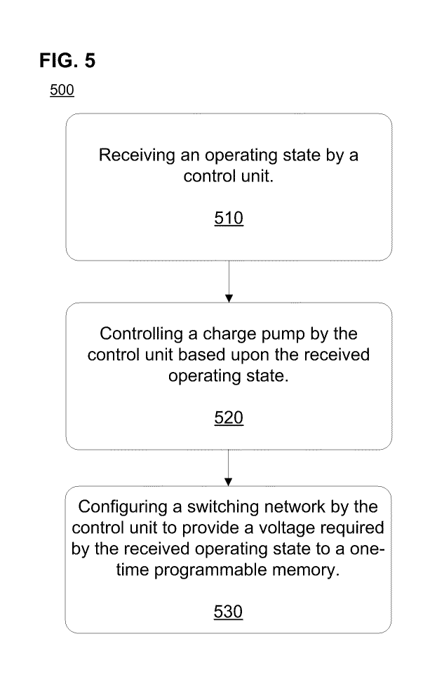

FIG. 5 illustrates one embodiment of a method for voltage generation and power switching. At block 510, an operating state is received by a control unit. At block 520, charge pump is controlled by the control unit based upon the received operating state. The charge pump may be connected to a first voltage and configured to generate a second voltage using the first voltage. At block 530, A switching network is configured by the control unit to provide a voltage to a one-time programmable memory. The voltage provided to the one-time programmable memory by the switching network may be a voltage required by the received operating state.

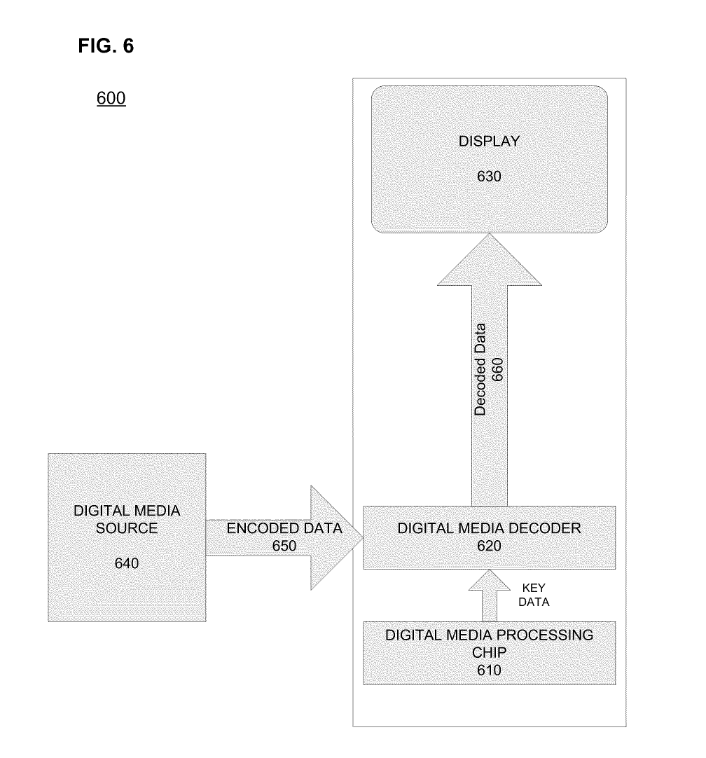

FIG. 6 illustrates one embodiment of a system for voltage generation and power switching. System 600 may be representative of a system or architecture suitable for use with one or more embodiments described herein. For example, system 600 may be device capable of transmitting, receiving, reading or writing digital media. System 600 may be a DVD player, Blu-ray Disc® player, desktop computer, laptop computer, mobile phone, portable computing device or other electronic device capable of processing digital media.

System 600 may include digital media source 640. Digital media source 640 may provide encoded digital media data 650 to digital media decoder 620. Digital media decoder 620 may require one or more keys to decode encoded data 650.

Digital media processing chip 610 may provide one or more keys to digital media decoder 620. Digital media processing chip 610 may include a control unit, an on-chip OTP memory, a switching network and a charge pump. The charge pump may be configured to supply the OTP memory with the voltage required to perform a read operation. During the read operation, digital media processing chip 620 may read a key from OTP memory and send the key to digital media decoder 620.

Digital media decoder 620 may use the received key to decode encoded data 650. Decoded data 660 may be sent to display 630. Display 630 may be a display device, such as a high-definition television or LCD display, capable of receiving and displaying digital media. The embodiments are not limited to these examples.

Numerous specific details have been set forth herein to provide a thorough understanding of the embodiments. It will be understood by those skilled in the art, however, that the embodiments may be practiced without these specific details. In other instances, well-known operations, components and circuits have not been described in detail so as not to obscure the embodiments. It can be appreciated that the specific structural and functional details disclosed herein may be representative and do not necessarily limit the scope of the embodiments.

Various embodiments may be implemented using hardware elements, software elements, or a combination of both. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

Some embodiments may be described using the expression “coupled” and “connected” along with their derivatives. These terms are not intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other.

Unless specifically stated otherwise, it may be appreciated that terms such as “processing,” “computing,” “calculating,” “determining,” or the like, refer to the action and/or processes of a computer or computing system, or similar electronic computing device, that manipulates and/or transforms data represented as physical quantities (e.g., electronic) within the computing system's registers and/or memories into other data similarly represented as physical quantities within the computing system's memories, registers or other such information storage, transmission or display devices. The embodiments are not limited in this context.

It should be noted that the methods described herein do not have to be executed in the order described, or in any particular order. Moreover, various activities described with respect to the methods identified herein can be executed in serial or parallel fashion.

Although specific embodiments have been illustrated and described herein, it should be appreciated that any arrangement calculated to achieve the same purpose may be substituted for the specific embodiments shown. This disclosure is intended to cover any and all adaptations or variations of various embodiments. It is to be understood that the above description has been made in an illustrative fashion, and not a restrictive one. Combinations of the above embodiments, and other embodiments not specifically described herein will be apparent to those of skill in the art upon reviewing the above description. Thus, the scope of various embodiments includes any other applications in which the above compositions, structures, and methods are used.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

We claim:

1. A voltage generation and power switching apparatus located on a chip comprising:
a control unit to receive an operating state;
a charge pump connected to a first voltage and configured to generate a second voltage using the first voltage, wherein the charge pump is activated by the control unit based upon the received operating state;
a one-time programmable memory connected to the charge pump via a switching network, wherein the switching network is configured by the control unit to provide a voltage required by the received operating state to the one-time programmable memory.

2. The voltage generation and power switching apparatus of claim 1, wherein the operating state is a programming state to program the one-time programmable memory with key data by a programming unit.

3. The voltage generation and power switching apparatus of claim 1, wherein the operating state is a read state to read key data from the one-time programmable memory during a read operation and communicate the key data to a decoder.

4. The voltage generation and power switching apparatus of claim 1, wherein the operating state is a quiet state to shut the down charge pump and shut down the one-time programmable memory.

5. The voltage generation and power switching apparatus of claim 1, wherein the first voltage is a chip supply voltage and the second voltage is required by the one-time programmable memory to perform a read operation during a read state.

6. The voltage generation and power switching apparatus of claim 5, wherein the first voltage is less than the second voltage.

7. The voltage generation and power switching apparatus of claim 1, wherein the control unit further comprises:
a voltage testing logic to test the second voltage provided over the switching network and to pause the current operating state if the second voltage provided over the switching network is above a maximum threshold level or below a minimum threshold level.

8. The voltage generation and power switching apparatus of claim 1 further comprising:
a memory interface to communicate with the one-time programmable memory during a read state;
a decoder to receive key data from the memory interface and generate decoded key data; and
a decoder memory buffer to store the decoded key data.

9. A method for voltage generation and power switching on a chip, comprising:
receiving an operating state by a control unit;
controlling a charge pump by the control unit based upon the received operating state, wherein the charge pump is connected to a first voltage and is configured to generate a second voltage using the first voltage; and
configuring a switching network by the control unit to provide a voltage required by the received operating state to a one-time programmable memory.

10. The method of claim 9, wherein the operating state is a programming state to program the one-time programmable memory with key data by a programming unit.

11. The method of claim 9, wherein the operating state is a read state to read key data from the one-time programmable memory and communicate the key data to a decoder.

12. The method of claim 9, wherein the operating state is a quiet state to shut the down charge pump and shut down the one-time programmable memory.

13. The method of claim 9, wherein the first voltage is a chip supply voltage and the second voltage is required by the one-time programmable memory to perform a read operation.

14. The method of claim 13, wherein the first voltage is less than the second voltage.

15. The method of claim 9, further comprising:
testing the provided voltage by a voltage testing logic located in the control unit;
wherein the voltage testing logic is configured to pause the current operating state if the voltage provided over the switching network is above a maximum threshold level or below a minimum threshold level.

16. The method of claim 9, further comprising:
accessing a key stored in the one-time programmable memory by a memory interface;
decoding the key using a decoder; and
storing the decoded key in a decoder memory buffer.

17. A voltage generation and power switching system, comprising:
a digital media source;
a display;
a decoder to receive encoded digital data from the digital media source and communicate decoded digital data to the display; and
a digital media processing chip to provide key data to the decoder, the digital media processing chip comprising:
a control unit to receive an operating state;
a charge pump connected to a first voltage and configured to generate a second voltage using the first voltage, wherein the charge pump is activated by the control unit based upon the received operating state;
a one-time programmable memory connected to the charge pump via a switching network, wherein the switching network is configured by the control unit to provide a voltage required by the received operating state to the one-time programmable memory.

18. The system of claim 17, wherein the operating state is a programming state to program the one-time programmable memory with key data by a programming unit.

19. The system of claim 17, wherein the operating state is a read state to read key data from the one-time programmable memory and communicate the key data to the decoder.

20. The system of claim 17, wherein the operating state is a quiet state to shut the down charge pump and shut down the one-time programmable memory.

21. The system of claim 17, wherein the first voltage is a chip supply voltage and the second voltage is required by the one-time programmable memory to perform a read operation.

22. The system of claim 21, wherein the first voltage is less than the second voltage.
